(19) United States
(12) Patent Application Publication
(10) Pub. No.: US 2025/0374415 A1
(43) Pub. Date: Dec. 4, 2025

(54) PCB CORE LAMINATE FOR WIRELESS POWER CHARGER AND METHOD OF MANUFACTURING THE SAME

(71) Applicants: Hyundai Motor Company, Seoul (KR); Kia Corporation, Seoul (KR); Amosense Co., Ltd., Cheonan-si (KR)

(72) Inventors: Youngmin Kim, Hwaseong-si (KR); Jae-Jun Ko, Cheonan-si (KR); Chol Han Kim, Cheonan-si (KR); Kwangyeol Kim, Cheonan-si (KR)

(21) Appl. No.: 18/813,388

(22) Filed: Aug. 23, 2024

(30) Foreign Application Priority Data
May 29, 2024 (KR) 10-2024-0070394

(51) Int. Cl. H05K 1/02; H05K 1/03; H05K 3/00

(52) U.S. Cl. CPC H05K 1/0201; H05K 1/0306; H05K 3/00

(57) ABSTRACT

An embodiment printed circuit board (PCB) core laminate for a wireless power charger is provided. The PCB core laminate includes a heat-dissipating material and a PCB core embedded in the heat-dissipating material, wherein the PCB core includes a PCB substrate and printed circuit patterns located on surfaces of the PCB substrate.

### CROSS-REFERENCE TO RELATED APPLICATIONS

This application claims the benefit of Korean Patent Application No. 10-2024-0070394, filed on May 29, 2024, which application is hereby incorporated herein by reference.

### TECHNICAL FIELD

The present disclosure relates to a printed circuit board (PCB) core laminate for a wireless power charger and a method of manufacturing the same.

### BACKGROUND

Wireless charging systems use high frequencies of several tens of kHz to several MHz. Generally, a higher frequency increases power transmission capacity and efficiency but decreases a current-carrying cross-sectional area of a copper wire due to the skin effect, resulting in an increase in resistance component.

In addition, as a resistance of a coil increases, a wireless power transmission system deteriorates in efficiency, resulting in an increase in conduction loss of the coil, which excessively increases the temperature of the coil, thereby causing a failure. To solve this problem that the resistance increases as the frequency increases, a Litz wire, which is made by twisting multiple thin strands of copper, is used.

A diameter of each strand of the Litz wire is selected according to a skin depth at an operating frequency, and the total number of strands is selected according to a current in the wire.

As the frequency increases, it is necessary to use a thinner copper wire, while an area occupied by a cross-sectional area of pure copper in an entire diameter of the Litz wire becomes smaller due to the shapes, insulations, and manufacturing tolerances of the copper wire strands, resulting in a problem that the diameter increases when compared to that of a single-strand wire having an equally current-carrying cross-sectional area.

In addition, the cost of the Litz wire increases significantly as the number of strands increases, and an occurrence of a problem that a strand is broken during a winding process decreases the number of valid strands and increases the conduction loss.

Furthermore, the coil using such a Litz wire commonly needs to be wound manually, whereby the inductance and the resistance of the coil are irregular, causing a problem that the productivity decreases.

A PCB-based coil has a limited current-carrying cross-sectional area when compared to that of the Litz coil, and thus, it is essential that a PCB be designed in such a manner that multiple layers are applied thereto.

The PCB core is designed according to a design guide to which the following Equation 1 is applied.

I=KΔT^{0.44}A^{0.725} Equation 1:

In Equation 1, I represents a current (A), A represents a cross-sectional area (square mile, mi²), ΔT represents a temperature rise (° C.), and k represents a constant (0.048: outer layer, 0.024: inner layer).

According to Equation 1 above, an area of a copper layer required to carry the same current under constant temperature rise conditions varies depending on whether the copper layer is inside or outside the PCB.

For example, when ΔT is 20° C., the width of the 3 oz copper layer that is capable of carrying a current of 23 A is 4.967 mm when it is an outer layer and 12.92 mm when it is an inner layer.

Therefore, when the copper layer is formed as a layer outside the PCB, the copper layer is capable of carrying the same current with a track width of less than or equal to half that when the copper layer is formed as a layer inside the PCB.

In a case where it is intended to design a PCB core laminate with a multilayer structure having the same track width while applying the design of the PCB according to Equation 1 as described above, it is not possible to design a PCB core laminate with a multilayer structure having the same pattern width because inner and outer layers need to have different track widths in order to maintain the same current density.

### SUMMARY

By using a heat-dissipating material and a PCB core embedded in the heat-dissipating material, embodiments of the present disclosure impart similar heat dissipation characteristics to a printed circuit pattern disposed on an upper surface of the PCB core and a printed circuit pattern disposed on a lower surface of the PCB core.

Accordingly, embodiments of the present disclosure are capable of providing a PCB core laminate having the same track width between the printed circuit pattern disposed on the upper surface of the PCB core and the printed circuit pattern disposed on the lower surface of the PCB core.

One embodiment of the present disclosure provides a printed circuit board (PCB) core laminate for a wireless power charger including a heat-dissipating material and a PCB core embedded in the heat-dissipating material, wherein the PCB core includes a PCB substrate and printed circuit patterns present on surfaces of the PCB substrate.

A plurality of PCB cores may be embedded in the heat-dissipating material, and the plurality of PCB cores may be stacked.

A plurality of heat-dissipating materials may be present with the PCB core embedded in each of the heat-dissipating materials, and the plurality of heat-dissipating materials may be stacked.

The heat-dissipating material may include one or more types of resins among an ethylene-based resin, an acrylic-based resin, and an amide-based resin.

The heat-dissipating material may include one or more types of inorganic materials between BN and Al₂O₃.

In the first PCB core or the second PCB core, the printed circuit patterns may be disposed on upper and lower surfaces of the PCB substrate.

In a cross-section of the PCB core laminate, the printed circuit pattern disposed on the upper surface of the PCB substrate and the printed circuit pattern disposed on the lower surface of the PCB substrate may be arranged to correspond to each other.

In a cross-section of the PCB core laminate, a difference in pattern width between the printed circuit pattern disposed on the upper surface of the PCB substrate and the printed circuit pattern disposed on the lower surface of the PCB substrate is smaller than or equal to 5%.

A cut-out portion penetrating a portion of the PCB substrate may be present in the PCB core.

The cut-out portion may be present through a central portion of the PCB substrate in the PCB core.

The cut-out portion may be filled with a heat-dissipating material.

In a cross-section of the PCB core laminate, heat-conducting frames may be connected to side end portions of the heat-dissipating material.

A magnetic sheet and a control PCB may be stacked on the heat-dissipating material.

A heat-dissipating material may be interposed between the magnetic sheet and the control PCB.

A method of manufacturing a PCB core laminate for a wireless power charger according to one embodiment includes integrating a PCB core into a heat-dissipating material by insert-injection.

The integration may be performed by insert-injecting a plurality of PCB cores into the heat-dissipating material in a stacked form.

The integration may be performed two or more times, and integrated heat-dissipating materials may be stacked.

By embedding the PCB core in the heat-dissipating material, the PCB core laminate according to one embodiment is capable of imparting similar heat dissipation characteristics to the printed circuit pattern disposed on the upper surface of the PCB core and the printed circuit pattern disposed on the lower surface of the PCB core.

In addition, the PCB core laminate according to one embodiment can be designed to have the same track width between the printed circuit pattern disposed on the upper surface of the PCB core and the printed circuit pattern disposed on the lower surface of the PCB core.

### BRIEF DESCRIPTION OF THE DRAWINGS

FIG. 1 is a diagram schematically illustrating a cross-section of a PCB core laminate in one embodiment.

FIGS. 2 to 9 are diagrams each schematically illustrating a cross-section of a PCB core laminate in another embodiment.

### DETAILED DESCRIPTION OF ILLUSTRATIVE EMBODIMENTS

The advantages and features of the technology disclosed herein and the methods for accomplishing the same will be apparent from the exemplary embodiments to be described below. However, modes for carrying out the present disclosure are not limited to the exemplary embodiments set forth herein. Unless otherwise defined, all terms (including technical and scientific terms) used herein have meanings commonly understood by those having ordinary skill in the art. In addition, terms defined in commonly used dictionaries are not to be ideally or exaggeratedly interpreted unless explicitly defined otherwise.

Throughout the specification, unless explicitly described to the contrary, the words “comprise/include,” and variations such as “comprises/includes” or “comprising/including,” will be understood to imply the inclusion of stated elements but not the exclusion of any other elements. Further, singular forms include plural forms unless mentioned otherwise.

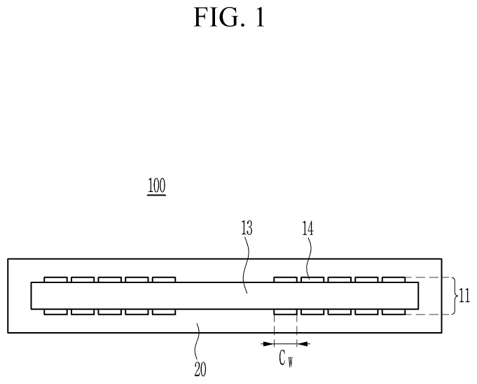

FIG. 1 schematically illustrates a cross-section of a PCB core laminate 100 in one embodiment. As shown in FIG. 1, the PCB core laminate 100 for a wireless power charger according to one embodiment includes a heat-dissipating material 20 and a printed circuit board (PCB) core 11 embedded in the heat-dissipating material 20, and the PCB core 11 includes a PCB substrate 13 and printed circuit patterns 14 present on surfaces of the PCB substrate 13. The structure of the PCB core laminate 100 in FIG. 1 merely exemplifies an embodiment of the present disclosure, and the present disclosure is not limited thereto. Therefore, various modifications may be made, for example, by adding other configurations to the configuration of the PCB core laminate 100 shown in FIG. 1.

The printed circuit pattern 14 disposed on an upper surface of the PCB substrate 13 and the printed circuit pattern 14 disposed on a lower surface of the PCB substrate 13 have different heat dissipation characteristics according to the upper and lower stack forms. Therefore, in order to maintain the same current density under different temperature conditions, it is inevitable to give a difference in track width between the printed circuit patterns 14.

In the PCB core laminate 100 according to one embodiment, since the PCB core 11 is embedded in the heat-dissipating material 20, it is possible to improve the heat dissipation characteristics of the printed circuit patterns 14 and also control the heat dissipation characteristics to a similar level. As a result, it is possible to minimize the difference in track width between the printed circuit patterns 14.

The embedment means that, in a cross-section of the PCB core laminate 100 in the thickness direction, all outer surfaces of the PCB core 11 are surrounded by the heat-dissipating material 20. Although it is shown in FIG. 1, etc., as an example that all outer surfaces of the PCB core 11 are in contact with the heat-dissipating material 20, a separate configuration may be interposed between the PCB core 11 and the heat-dissipating material 20.

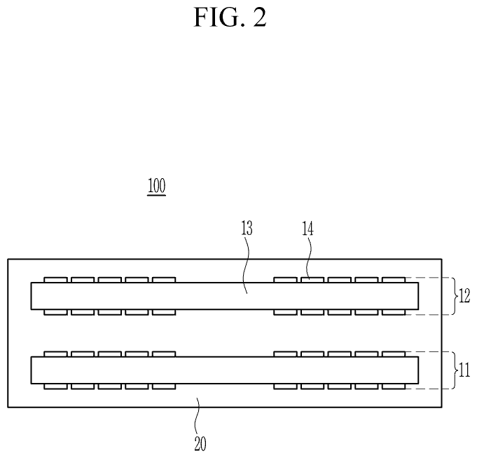

FIG. 2 schematically illustrates a cross-section of a PCB core laminate 100 in another embodiment. As shown in FIG. 2, the PCB core laminate 100 in another embodiment includes a plurality of PCB cores 11 and 12 embedded in the heat-dissipating material, and the plurality of PCB cores 11 and 12 are stacked. In this case, the stacking direction is the thickness direction of the PCB core laminate 100.

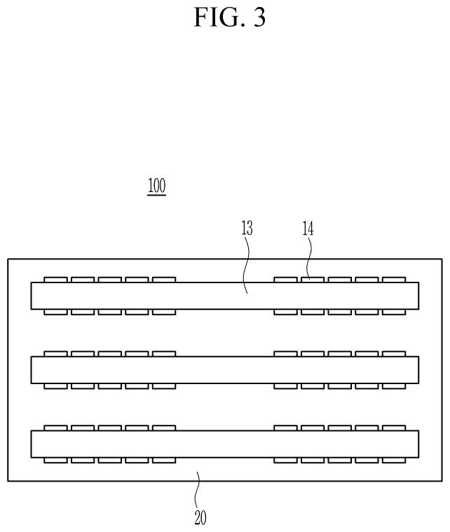

FIG. 3 schematically illustrates a cross-section of a PCB core laminate 100 in another embodiment. As shown in FIG. 3, the PCB core laminate 100 in another embodiment includes three or more PCB cores 11 and 12 embedded and stacked in the heat-dissipating material. In this case, since the PCB cores 11 and 12 are embedded in the heat-dissipating material 20, it is possible to adjust the heat dissipation characteristics between the printed circuit patterns to be similar to each other.

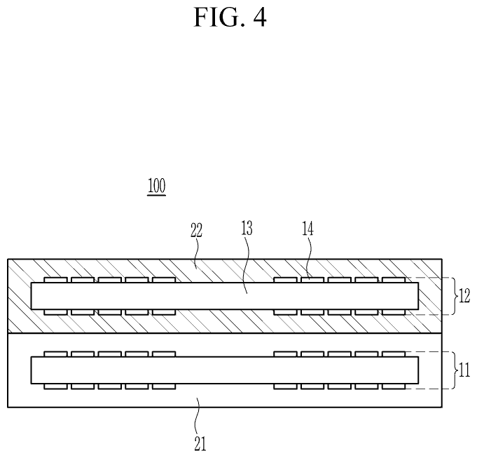

FIG. 4 schematically illustrates a cross-section of the PCB core laminate 100 in another embodiment. As shown in FIG. 4, the PCB core laminate 100 in another embodiment includes a plurality of heat-dissipating materials 21 and 22, and the PCB cores 11 and 12 embedded in the respective heat-dissipating materials 21 and 22, and the plurality of heat-dissipating materials 21 and 22 are stacked.

The plurality of heat-dissipating materials 21 and 22 may be distinguished by different composition materials or different ratios between the materials. Alternatively, the plurality of heat-dissipating materials 21 and 22 may be distinguished by different thermal conductivities.

The heat-dissipating material 20 may include one or more types of resins among an ethylene-based resin, an acrylic-based resin, and an amide-based resin. More specifically, the heat-dissipating material 20 may include polypropylene (PP) or polyamide 6 (PA6).

The heat-dissipating material 20 may include one or more types of inorganic materials between BN (boron nitride) and Al₂O₃ (aluminum oxide). These inorganic materials have excellent thermal conductivity and impart heat dissipation performance to the heat-dissipating material 20.

The printed circuit pattern 14 may include a conductive material, more particularly copper. Although not illustrated in FIG. 1, etc., the conductive material may be wound in multiple turns from the outside to the inside on the surface of the PCB substrate 13 to form a spiral track. Since the material and the pattern shape of the printed circuit pattern 14 are widely known, the detailed description thereof is omitted.

As shown in FIG. 1, the printed circuit patterns 14 may be arranged on both upper and lower surfaces of the PCB substrate 13. In addition, in a cross-section of the PCB core laminate 100, the printed circuit pattern disposed on the upper surface of the PCB substrate and the printed circuit pattern disposed on the lower surface of the PCB substrate may be arranged to correspond to each other.

In addition, as shown in FIGS. 2 and 3, the printed circuit patterns 14 disposed on the first PCB core 11 and the printed circuit patterns 14 disposed on the second PCB core 12 may be arranged to correspond to each other. The corresponding arrangement means that the printed circuit patterns 14 are present in parallel to each other at the same location in the thickness direction of the PCB core laminate 100.

Assuming that there is no heat-dissipating material 20, depending on stack forms, while the printed circuit pattern 14 present on a lower surface of the first PCB core 11 and the printed circuit pattern 14 present on an upper surface of the second PCB core 12 are easy to dissipate heat from because they are present in contact with air on a surface outside the PCB core laminate, the printed circuit pattern 14 present on an upper surface of the first PCB core 11 and the printed circuit pattern 14 present on a lower surface of the second PCB core 12 are difficult to dissipate heat from because they are present on a surface inside the PCB core laminate. Due to this difference in heat dissipation characteristic, it is inevitable to give a difference in track width between the printed circuit patterns 14 in order to maintain the same current density.

According to one embodiment, by embedding the first PCB core 11 and the second PCB core 12 inside the heat-dissipating material 20, the difference in track width between the printed circuit patterns 14 can be minimized. More specifically, the difference in pattern width C_{W} between the printed circuit pattern 14 disposed on the upper surface of the PCB substrate 13 and the printed circuit pattern 14 disposed on the lower surface of the PCB substrate 13 may be smaller than or equal to 5%. The pattern width C_{W} of the printed circuit pattern 14 may be obtained by [difference in width between printed circuit patterns]/[average of widths of printed circuit patterns] at corresponding locations. More specifically, the difference in pattern width C_{W} may be smaller than or equal to 1%.

The PCB substrate 13 is a printed circuit board and refers to a board on which various electronic components such as IC chips, resistors, coils, and capacitors are connected to a plastic plate with copper wiring printed thereon.

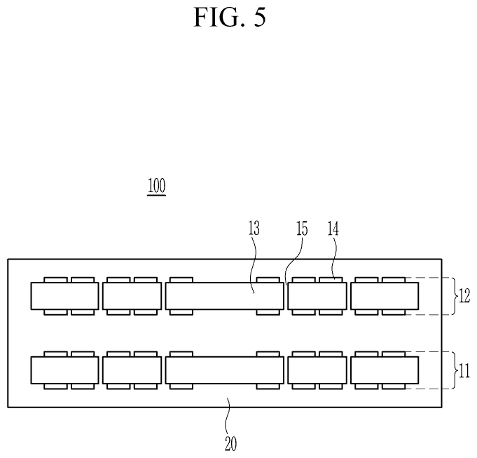

As shown in FIG. 5, a cut-out portion 15 penetrating a portion of the PCB substrate 13 may be present in each of the PCB cores 11 and 12. The cut-out portion 15 may be present at a location of the PCB substrate 13 where the printed circuit pattern 14 is not disposed. Since the cut-out portion 15 is present in the PCB substrate 13, the heat dissipation characteristic can be further improved.

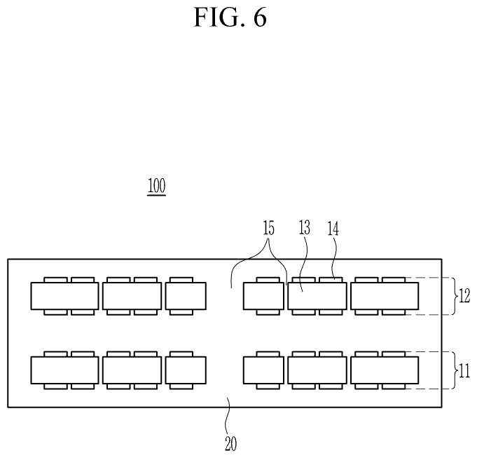

In addition, as illustrated in FIG. 6, a cut-out portion 15 may be present in a central portion of the PCB substrate 13. The central portion refers to a location from the center of the PCB substrate 13 to the printed circuit patterns 14 that are located closest to the center of the PCB substrate 13 in the cross-section of the PCB core laminate 100.

As shown in FIGS. 5 and 6, the cut-out portions 15 may be filled with a heat-dissipating material. The filled heat-dissipating material may be the same as the material of the heat-dissipating material 20 in which the PCB cores 11 and 12 are embedded, and the description thereof is omitted.

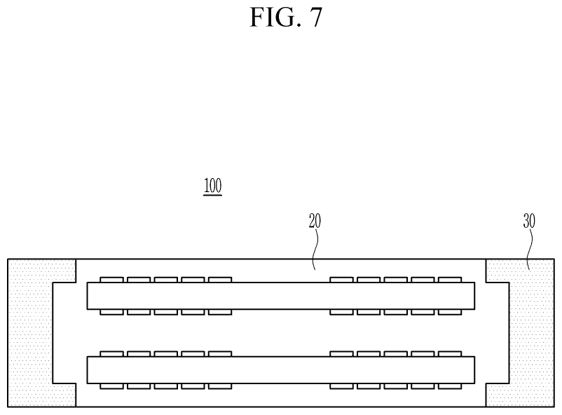

As shown in FIG. 7, in the cross-section of the PCB core laminate 100, heat-conducting frames 30 may be connected to side end portions of the heat-dissipating material 20. This can further improve the heat dissipation characteristic. The heat dissipation characteristic can be further improved by adding a water-cooling or air-cooling means to the heat-conducting frames 30. Specifically, the side end portions of the heat-dissipating material 20 may be embedded between the heat-conducting frames 30.

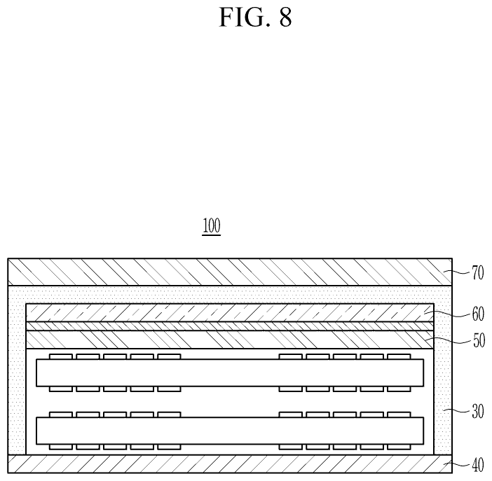

In addition, additional layers may be stacked on the PCB cores 11 and 12 if necessary. As shown in FIG. 8, a magnetic sheet 50 and a control PCB 60 may be stacked on the PCB core 12. As the magnetic sheet 50, an amorphous sheet or a ferrite sheet made of an amorphous ribbon having a high magnetic permeability may be used. Any amorphous sheet having a high magnetic permeability may be used. For example, an amorphous ribbon in the form of a thin plate made of an Fe-based, Co-based, or Ni-based amorphous alloy may be used. Alternatively, for the magnetic sheet 50, permalloy having excellent soft magnetic properties, molypermalloy powder (MPP) containing molybdenum (Mo), or the like may be applied.

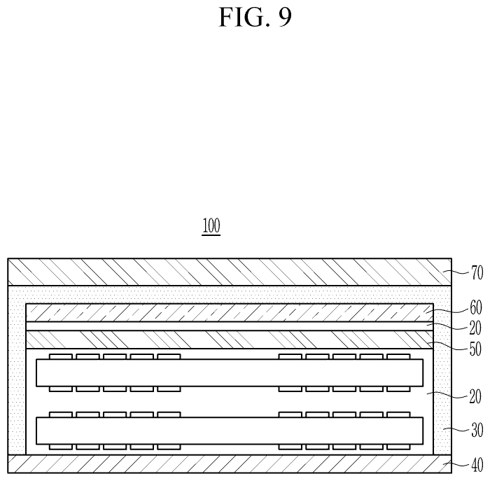

In addition, as shown in FIG. 9, a heat-dissipating material 20 may be interposed between the magnetic sheet 50 and the control PCB 60. This can further improve the heat dissipation characteristic of the PCB core laminate 100.

As shown in FIGS. 8 and 9, the PCB core laminate 100 may further include a heat-conducting frame 30, a lower cover 40 disposed under the first PCB core 11, and a cooling module 70 connected to the heat-conducting frame 30.

A method of manufacturing a PCB core laminate 100 for a wireless power charger according to one embodiment includes integrating a PCB core 11 or 12 into a heat-dissipating material 20 by insert-injection. The PCB cores 11 and 12 and the heat-dissipating material 20 are the same as described above, and thus, the redundant description is omitted.

The integration may be performed by insert-injecting a plurality of PCB cores 11 and 12 into the heat-dissipating material in a stacked form. Alternatively, the integration may be performed two or more times, and integrated heat-dissipating materials may be stacked.

The PCB core laminate 100 according to one embodiment may be usefully used for a wireless power charger. More specifically, the PCB core laminate 100 according to one embodiment may be usefully used for the purpose of charging a battery that supplies electrical energy to a motor for driving an electric vehicle.

Specific examples of embodiments of the disclosure will be presented below. However, the examples described below are only intended to specifically exemplify or explain embodiments of the disclosure, and the scope of the disclosure should not be limited thereby.

### Heat Dissipation Characteristic

The PCB core laminate 100 illustrated in FIG. 8 was manufactured. The lower cover 40 was made of polycarbonate (thermal conductivity: 0.2 W/m K), the PCB substrates 13 and 60 were made of FR4 (thermal conductivity: 0.35 W/m K), the printed circuit pattern 14 was made of Cu (thermal conductivity: 387.6 W/m K), the magnetic sheet 50 was made of a ferrite sheet (plane: 2.057 and through: 4.665), the heat-conducting frame 30 was made of Al die-cast (thermal conductivity: 100 W/m K), and the cooling module 70 was made of Al die-cast (thermal conductivity: 100 W/m K).

In Example 1, a first PCB core 11 and a second PCB core 12 were embedded in a heat-dissipating material 20 having a thermal conductivity of 1 W/m K. In Example 2, a first PCB core 11 and a second PCB core 12 were embedded in a heat-dissipating material 20 having a thermal conductivity of 3 W/m K.

In a comparative example, a first PCB core 11 and a second PCB core 12 were placed with an empty space therebetween without a heat-dissipating material 20.

After operating the PCB core laminate 100, its temperature was measured. The temperature was 88.6° C. in Example 1 and 81.6° C. in Example 2, while the temperature was 366.4° C. in the comparative example, confirming that an excellent heat dissipation characteristic was obtained by embedding the PCB cores 11 and 12 in the heat-dissipating material 20.

Although the preferred exemplary embodiments of the present disclosure have been described in detail above, the scope of the present disclosure is not limited thereto, and various modifications and improvements made by those skilled in the art using the basic concepts of embodiments of the present disclosure defined in the following claims also fall within the scope of the present disclosure.

The following reference identifiers may be used in connection with the figures to describe various features of embodiments of the present disclosure.

| | |
|---|---|
| 100: PCB core laminate | 11, 12: PCB core |
| 11: first PCB core | 12: second PCB core |
| 13: PCB substrate | 14: printed circuit pattern |
| 15: cut-out portion | 20, 21, 22: heat-dissipating material |
| 21: first heat-dissipating material | 22: second heat-dissipating material |
| 30: heat-conducting frame | 40: lower cover |
| 50: magnetic sheet | 60: control PCB |
| 70: cooling module | |

What is claimed is:

1. A printed circuit board (PCB) core laminate for a wireless power charger, the PCB core laminate comprising:
a heat-dissipating material; and
a PCB core embedded in the heat-dissipating material, wherein the PCB core comprises a PCB substrate and printed circuit patterns located on surfaces of the PCB substrate.

2. The PCB core laminate of claim 1, wherein:
a plurality of PCB cores are embedded in the heat-dissipating material; and
the plurality of PCB cores are stacked.

3. The PCB core laminate of claim 1, wherein:
a plurality of heat-dissipating materials are present;
a plurality of PCB cores are embedded in each of the heat-dissipating materials, respectively; and
the plurality of heat-dissipating materials are stacked.

4. The PCB core laminate of claim 1, wherein the heat-dissipating material comprises one or more types of resins among an ethylene-based resin, an acrylic-based resin, and an amide-based resin.

5. The PCB core laminate of claim 4, wherein the heat-dissipating material further comprises one or more types of inorganic materials that include BN or Al₂O₃.

6. The PCB core laminate of claim 1, wherein, in the PCB core, the printed circuit patterns are disposed on upper and lower surfaces of the PCB substrate.

7. The PCB core laminate of claim 6, wherein, in a cross-section of the PCB core laminate, the printed circuit pattern disposed on the upper surface of the PCB substrate and the printed circuit pattern disposed on the lower surface of the PCB substrate are arranged to correspond to each other.

8. The PCB core laminate of claim 6, wherein, in a cross-section of the PCB core laminate, a difference in pattern width between the printed circuit pattern disposed on the upper surface of the PCB substrate and the printed circuit pattern disposed on the lower surface of the PCB substrate is smaller than or equal to 5%.

9. The PCB core laminate of claim 1, wherein a cut-out portion penetrating a portion of the PCB substrate is present in the PCB core.

10. The PCB core laminate of claim 9, wherein the cut-out portion is present through a central portion of the PCB substrate in the PCB core.

11. The PCB core laminate of claim 10, wherein the cut-out portion is filled with the heat-dissipating material.

12. The PCB core laminate of claim 9, wherein the cut-out portion is filled with the heat-dissipating material.

13. The PCB core laminate of claim 1, wherein, in a cross-section of the PCB core laminate, heat-conducting frames are connected to side end portions of the heat-dissipating material.

14. The PCB core laminate of claim 1, wherein a magnetic sheet and a control PCB are stacked on the heat-dissipating material.

15. The PCB core laminate of claim 14, wherein a second heat-dissipating material is interposed between the magnetic sheet and the control PCB.

16. A method of manufacturing a printed circuit board (PCB) core laminate for a wireless power charger, the method comprising:
integrating a PCB core into a heat-dissipating material by insert-injection.

17. The method of claim 16, wherein integrating the PCB core is performed by insert-injecting a plurality of PCB cores into the heat-dissipating material in a stacked form.

18. The method of claim 16, wherein:
integrating the PCB core is performed two or more times; and
integrated heat-dissipating materials are stacked.

19. The method of claim 16, wherein:
the PCB core comprises a PCB substrate and printed circuit patterns present on surfaces of the PCB substrate;
a cut-out portion penetrating a portion of the PCB substrate is present in the PCB core;
the cut-out portion is filled with the heat-dissipating material; and
the heat-dissipating material comprises one or more types of resins among an ethylene-based resin, an acrylic-based resin, and an amide-based resin.

20. The method of claim 19, wherein the heat-dissipating material further comprises one or more types of inorganic materials between BN and Al₂O₃.
